(19) United States
(12) Patent Application Publication
(10) Pub. No.: US 2017/0250236 A1
(43) Pub. Date: Aug. 31, 2017

(54) DISPLAY PANEL, FABRICATION METHOD AND ELECTRONIC DEVICE

(71) Applicants: SHANGHAI TIANMA AM-OLED CO., LTD., Shanghai (CN); TIANMA MICRO-ELECTRONICS CO., LTD., Shenzhen (CN)

(72) Inventors: Zhiyong Xiong, Shanghai (CN); Yuji Hamada, Shanghai (CN)

(21) Appl. No.: 15/191,174

(22) Filed: Jun. 23, 2016

(30) Foreign Application Priority Data
Feb. 29, 2016 (CN) 201610112703.2

(51) Int. Cl. H01L 27/32; H01L 51/56; H01L 51/00

(52) U.S. Cl. CPC H01L 27/3246; H01L 51/001; H01L 51/0018; H01L 51/56; H01L 2227/323

(57) ABSTRACT

A display panel, an electronic device and a fabrication method are provided. The display panel includes: a substrate, an anode layer and a cathode layer arranged on a same side of the substrate, a luminescent function layer and a partition structure. The anode layer is arranged between the substrate and the cathode layer. The luminescent function layer is arranged between the anode layer and the cathode layer and includes at least one sub-function layer and multiple pixel units arranged in an array. The partition structure is arranged between at least two of the pixel units adjacent to each other in a first direction. The partition structure is configured to break at least one sub-function layer at a location between the at least two of the pixel units, and the first direction is parallel to the substrate.

### CROSS REFERENCE OF RELATED APPLICATION

The present application claims the priority to Chinese Patent Application No. 201610112703.2, titled “DISPLAY PANEL, FABRICATION METHOD AND ELECTRONIC DEVICE”, filed on Feb. 29, 2016 with the State Intellectual Property Office of the PRC, which is incorporated herein by reference in its entirety.

### FIELD

The disclosure relates to the technical field of display device, and in particular to a display panel, a fabrication method and an electronic device.

### BACKGROUND

In recent years, flat panel displays such as a LCD display and an OLED display generally become mainstream products in the display market, instead of CRT displays. The OLED display is considered as a display with optimal development potential in the art, since it has advantages such as self-luminescent, a low driving voltage, a high luminous efficiency, a short response time, a high sharpness and contrast, a wide viewable angle range, a wide using temperature range and achievable of flexible display and large area full color display.

A main structure of the OLED display is an OLED component, the OLED component includes an anode and a cathode arranged opposite to each other, and a function layer arranged between the anode and the cathode. A luminescent principle of the OLED component is that: when being driven by an electric field between the cathode and the anode, a semiconductor material and an organic luminescent material emit a light by injecting and combining carriers.

With the continuously improved resolution of display, the number of pixel units is increasing and a space between the pixel units is decreasing. In addition, with the improved luminous efficiency of the luminescent material of the OLED display, a high brightness can be achieved with a low current and a low voltage, thereby reducing power consumption. Since the space between the pixel units is decreased and the luminescent material can emit a light in a case of a small current, a small current leaked from a pixel unit to another pixel unit adjacent to the pixel unit may make the luminescent material with high luminous efficiency emit a light, thereby making the another pixel unit adjacent to the pixel unit, which should not emit a light, emit a light. The light being emitted due to a leakage current is called a leakage luminescence phenomenon. And an image display effect of the OLED display may be affected by a leakage luminescence phenomenon.

### SUMMARY

In order to address the above issue, a display panel, a fabrication method and an electronic device are provided according to the present disclosure, to avoid a leakage luminescence phenomenon caused by a leakage current.

In order to achieve the above object, the following technical solutions are provided according to the present disclosure.

A display panel includes a substrate, an anode layer, a cathode layer, a luminescent function layer, and a partition structure. The anode layer and the cathode layer are arranged on a same side of the substrate and opposite to each other in a direction perpendicular to the substrate. The anode layer is arranged between the substrate and the cathode layer and includes multiple anodes. The luminescent function layer is arranged between the anode layer and the cathode layer. The luminescent function layer includes at least one sub-function layer and multiple pixel units arranged in an array, and the pixel units are arranged respectively opposite to the anodes in the direction perpendicular to the substrate. The partition structure is arranged between at least two of the pixel units adjacent to each other in a first direction. The partition structure is configured to break at least one sub-function layer at a location between the at least two of the pixel units, and the first direction is parallel to the substrate.

An electronic device including the above display panel is further provided according to the present disclosure.

A fabrication method for fabricating the above display panel is further provided according to the present disclosure. The fabrication method includes preparing a substrate, forming an anode layer on a surface of the substrate, patterning the anode layer to form multiple anodes arranged in an array, forming a luminescent function layer on a surface of the patterned anode layer, and forming a cathode layer on a surface of the luminescent function layer. The luminescent function layer includes at least one sub-function layer. The luminescent function layer includes multiple pixel units arranged in an array. The pixel units are arranged respectively opposite to the anodes in a direction perpendicular to the substrate. A partition structure is arranged between two of the pixel units adjacent to each other in a first direction. The partition structure is configured to break at least one sub-function layer at a location between the two of the pixel units, and the first direction is parallel to the substrate.

It can be seen from the above description that, in the display panel according to the present disclosure, the partition structure is arranged between at least two of the pixel units adjacent to each other in the first direction, the partition structure is configured to break at least one sub-function layer at a location between the at least two of the pixel units adjacent to each other. In this case, a leakage luminescence phenomenon due to a small space between the at least two of the pixel units is avoided, thereby ensuring an image display effect. In the fabrication method according to the present disclosure, the above display panel may be fabricated with a simple fabrication process and a low fabrication cost, since a mature photoetching process and a mature evaporation process are adopted. The electronic device according to the present disclosure includes the above display panel, hence has a good display effect.

### BRIEF DESCRIPTION OF THE DRAWINGS

The drawings to be used in the description of the embodiments or the conventional technology are described briefly as follows, so that the technical solutions according to the embodiments of the present disclosure or according to the conventional technology become clearer. It is apparent that the drawings in the following description only illustrate some embodiments of the present disclosure. For those skilled in the art, other drawings may be obtained based on these drawings without any creative work.

FIG. 1 is a schematic structural diagram of a display panel according to an embodiment of the present disclosure;

FIG. 2 is a schematic structural diagram of a display panel according to another embodiment of the present disclosure;

FIG. 3 is a top view of a display panel according to an embodiment of the present disclosure;

FIG. 4 is a top view of a display panel according to another embodiment of the present disclosure;

FIG. 5a is a schematic structural diagram of a display panel according to another embodiment of the present disclosure;

FIG. 5b is a schematic structural diagram of a display panel according to another embodiment of the present disclosure;

FIG. 6 is a schematic flowchart of a fabrication method according to an embodiment of the present disclosure;

FIG. 7 is a schematic diagram of a principle of forming a luminescent function layer according to an embodiment of the present disclosure;

FIG. 8 is a schematic flowchart of a method for forming a luminescent function layer and a cathode layer according to an embodiment of the present disclosure;

FIG. 9 is a schematic flowchart of a method for fabricating a protrusion structure according to an embodiment of the present disclosure;

FIG. 10 is a schematic flowchart of a method for fabricating a protrusion structure according to another embodiment of the present disclosure; and

FIG. 11 is a schematic structural diagram of an electronic device including a display panel according to an embodiment of the present disclosure.

### DETAILED DESCRIPTION OF EMBODIMENTS

The technical solutions according to the embodiments of the present disclosure are described clearly and completely in conjunction with the drawings hereinafter. It is apparent that the described embodiments are only a few rather than all of the embodiments according to the present disclosure. Any other embodiments obtained by those skilled in the art based on the embodiments in the present disclosure without any creative work fall into the scope of the present disclosure.

As described in the background, with the continuously improved resolution of the existing display panel, the number of pixel units is increasing and a space between the pixel units is decreasing. In addition, with the improved luminous efficiency of the luminescent material for the OLED display, a high brightness can be achieved with a low current and a low voltage, thereby reducing power consumption. In this case, a small current leaked from a pixel unit to another pixel unit adjacent to the pixel unit may make the luminescent material with high luminous efficiency emit a light, thereby making the another pixel unit adjacent to the pixel unit, which should not emit a light, emit a light and causing a leakage luminescence phenomenon. And an image display effect of the OLED display may be affected by the leakage luminescence phenomenon.

In order to address the above issue, a display panel is provided according to an embodiment of the present disclosure. The display panel includes a substrate, an anode layer, a cathode layer, a luminescent function layer, and a partition structure. The anode layer and the cathode layer are arranged on a same side of the substrate and opposite to each other in a direction perpendicular to the substrate. The anode layer is arranged between the substrate and the cathode layer and includes multiple anodes. The luminescent function layer is arranged between the anode layer and the cathode layer. The luminescent function layer includes at least one sub-function layer and multiple pixel units arranged in an array, and the pixel units are arranged respectively opposite to the anodes in the direction perpendicular to the substrate. The partition structure is arranged between at least two of the pixel units adjacent to each other in a first direction. The partition structure is configured to break at least one sub-function layer at a location between the at least two of the pixel units, and the first direction is parallel to the substrate.

In the display panel, the partition structure is arranged between at least two of the pixel units adjacent to each other in the first direction. The partition structure is configured to break at least one sub-function layer at a location between the at least two of the pixel units adjacent to each other, thereby cutting a current leakage channel between the at least two of the pixel units and avoiding a leakage current between the at least two of the pixel units. In this case, a leakage luminescence phenomenon due to a small space between the at least two of the pixel units may be avoided, thereby ensuring an image display effect.

To make the technical solutions of the present disclosure clearer, the above technical solutions are described in detail in conjunction with the drawings hereinafter.

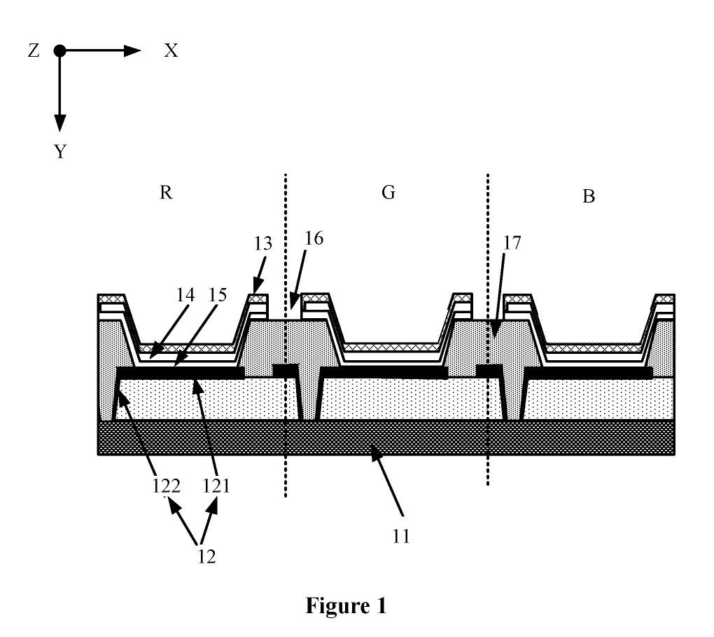

Reference is made to FIG. 1, which is a schematic structural diagram of a display panel according to an embodiment of the present disclosure. The display panel includes a substrate 11, an anode layer 12, a cathode layer 13 and a luminescent function layer. The anode layer 12 and the cathode layer 13 are arranged on a same side of the substrate 11 and opposite to each other in a direction perpendicular to the substrate. The luminescent function layer is arranged between the anode layer 12 and the cathode layer 13 and includes at least one sub-function layer. The substrate 11 includes multiple thin-film transistors for a display driving and/or a touch driving.

In FIG. 1, two sub-function layers of the luminescent function layer are shown, including an organic luminescent layer 14 and a cavity transmission layer 15. It should be noted that, a structure of the luminescent function layer includes, but is not limited to, the embodiment shown in FIG. 1.

The anode layer 12 is arranged between the substrate 11 and the cathode layer 13 and the anode layer 12 includes multiple anodes.

The luminescent function layer includes multiple pixel units arranged in an array. The pixel units are arranged respectively opposite to the anodes in the direction perpendicular to the substrate. In the embodiment shown in FIG. 1, it is shown a red pixel unit R, a green pixel unit G and a blue pixel unit B, which are adjacent successively in a first direction X.

A partition structure 16 is arranged between at least two of the pixel units adjacent to each other in the first direction X. The partition structure 16 is configured to break at least one sub-function layer at a location between the at least two of the pixel units. The first direction X is parallel to the substrate 11.

In the embodiment shown in FIG. 1, the partition structure 16 is arranged between any two of the pixel units adjacent to each other in the first direction X. The partition structure 16 is configured to break all sub-function layers of the luminescent function layer at a location between the two of the pixel units adjacent to each other in the first direction X.

Optionally, a pixel definition structure 17 may be arranged between two of the pixel units adjacent to each other in the first direction X. The anode layer 12 includes a luminescent region 121 and a connection region 122. The connection region 122 is electrically connected to a thin-film transistor.

In the direction perpendicular to the substrate 11, a projection of the pixel definition structure 17 on a surface of the substrate 11 does not overlap with a projection of the luminescent region 121 on the surface of the substrate 11. The pixel definition structure 17 is configured to form multiple pixel regions arranged in an array on the surface of the substrate 11, the cathode layer and the luminescent function layer corresponding to the pixel units are arranged in the pixel regions.

In order to ensure a luminous efficiency, in the direction perpendicular to the substrate 11, a projection of the partition structure 16 on the surface of the substrate 11 does not overlap with the projection of the luminescent region 121 on the surface of the substrate 11.

In the embodiment shown in FIG. 1, the partition structure 16 is an opening formed in a sub-function layer at the location between two of the pixel units, and the opening is located on a side of the pixel definition structure 17 facing away from the substrate 11. In this embodiment, the partition structure 16 is an opening formed in the sub-function layer and the partition structure 16 is configured to break the sub-function layer at a location between the two of the pixel units. In a case that the partition structure 16 is an opening, the partition structure 16 is formed simply. In forming the opening, the partition structure may be formed by only using a mask having a preset shape, and it is unnecessary to break the luminescent function layer by an etching process, thereby avoiding damage on the anode layer due to overetching.

The partition structure 16 is further configured to break the cathode layer 13 at the location between the two of the pixel units adjacent to each other in the first direction X.

It should be noted that, in the drawings according to the embodiments of the present disclosure, for a good illustration, a first direction X, a third direction Y and a second direction Z are defined to form an XYZ coordinate system. The above direction perpendicular to the substrate is the third direction Y.

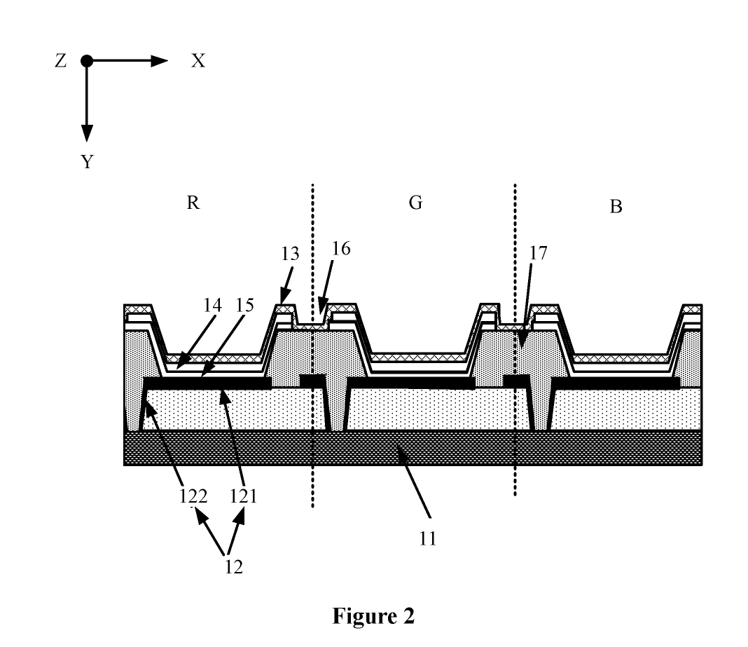

In other embodiments, the cathode layer may be an entire layer, that is, the cathode is not broken at the locations between pixel units. In this case, a structure of the display panel is as shown in FIG. 2, which is a schematic structural diagram of a display panel according to another embodiment of the present disclosure.

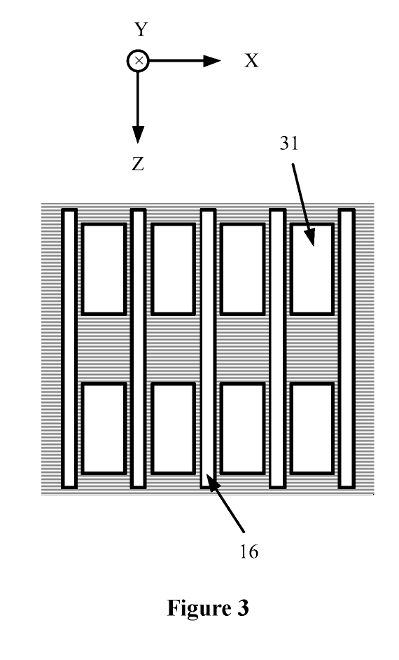

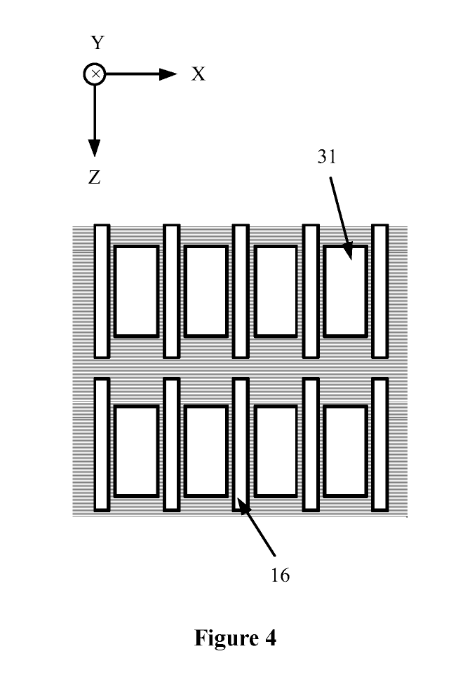

In the above display panel, the partition structure may extend in the second direction Z which is perpendicular to the first direction X. The display panel includes a display region in which the pixel units are arranged. In this case, the partition structure may be arranged as shown in FIG. 3 and FIG. 4.

Reference is made to FIG. 3, which is a top view of a display panel according to an embodiment of the present disclosure. The display panel shown in FIG. 3 includes multiple pixel units 31 arranged in an array in the display region. Partition structures are arranged between pixel units 31 adjacent to each other in the first direction X. In the embodiment, the partition structure 16 passes through the display region. Specifically, a row direction of the array is parallel to the first direction X and a column direction of the array is parallel to the second direction Z. The partition structure 16 is arranged between two adjacent columns of pixel units and passes through a region between the two columns of pixel units.

Reference is made to FIG. 4, which is a top view of a display panel according to another embodiment of the present disclosure. The embodiment shown in FIG. 4 differs from the embodiment shown in FIG. 3 in that: the partition structure 16 passes through a region between two pixel units 31 adjacent to each other in the first direction X and is broken between two rows of pixel units.

In some embodiments, in the display panel according to the embodiment of the present disclosure, the pixel units may include a first color pixel unit. In the first direction, partition structures are arranged respectively between the first color pixel unit and other pixel units, and the other pixel units are located on two sides of the first color pixel unit and adjacent to the first color pixel unit. Specifically, the display panel includes a red pixel unit, a green pixel unit and a blue pixel unit. The first color pixel unit is the green pixel unit. Since the human eye is sensitive to a green light band, the green pixel unit is separated from other color pixel units on the two sides of the green pixel unit in the first direction by arranging the partition structures, thereby avoiding a light leakage of the green pixel unit due to a leakage current and ensuring an image display effect. If a distance between two of the pixel units adjacent to each other in the first direction is shorter than a preset distance, the partition structure is arranged between the two of the pixel units. The distance between the pixel units and a space between the luminescent regions. Optionally, the preset distance may be 80 micrometers.

Generally, in a case that the multiple pixel units of the display panel are arranged in an array, a structure such as a gate line and a thin-film transistor needs to be arranged between two rows of pixel units. Therefore, a space between two pixel units adjacent to each other in the column direction is large and a leakage current between the two pixel units is not enough to cause a leakage luminescence phenomenon. The space between two columns of pixel units is small, a space between two pixel units adjacent to each other in the row direction may be reduced greatly to improve a resolution of the display panel. Therefore, in the embodiment of the present disclosure, it is preferable to arrange the partition structure between two pixel units adjacent to each other in the row direction, to prevent the leakage luminescence phenomenon.

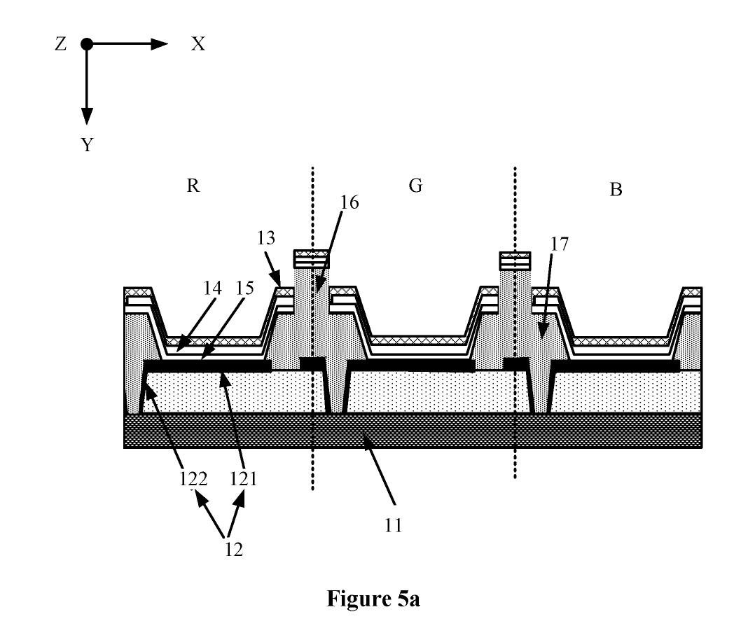

In an embodiment of the present disclosure, the partition structure may be a protrusion structure. In this case, a structure of the display panel is as shown in FIG. 5a or FIG. 5b. The display panels shown in FIG. 5a and FIG. 5b differ from those described in the above embodiments in that: the partition structure is implemented in different ways. In the embodiments shown in FIG. 1 and FIG. 2, the partition structure 16 is the opening formed in the luminescent function layer. In the embodiments shown in FIG. 5a and FIG. 5b, the partition structure 16 is the protrusion structure formed between two pixel units. The protrusion structure is located on a side of the pixel definition structure facing away from the substrate, and is configured to break the cathode layer and the luminescent function layer at the location between the two pixel units. In FIG. 5a, the partition structure 16 is formed with a same dielectric layer as the pixel definition structure 17. In FIG. 5b, the partition structure 16 is formed with a dielectric layer different from another dielectric layer for forming the pixel definition structure 17.

In the display panels according to the embodiments of the present disclosure, in the display panel with the structure shown in FIG. 1 and FIG. 2, the partition structure may be formed as an opening in the luminescent function layer through forming the luminescent function layer with a mask having a preset shape by an evaporation process. In the display panel with the structure shown in FIG. 5a and FIG. 5b, the partition structure may be formed as a protrusion structure by a photoetching process. The protrusion structure can break the luminescent function layer and the cathode layer at a location of the protrusion structure when the luminescent function layer and the cathode layer are formed by an evaporation process.

In the display panel according to the embodiment of the present disclosure, the partition structure is arranged on the pixel definition structure, and an aperture ratio of the pixel units and a resolution of the display panel are not affected. A leakage current between two pixel units is cut off by forming the partition structure in the luminescent function layer, instead of breaking the cathode layer, thereby cutting off the leakage current more effectively. In addition, no additional wiring is needed, the fabrication process is simple, and the aperture ratio and the resolution may not be affected.

As can be seen from the above description, in the display panel according to the embodiment of the present disclosure, a current leakage channel between two pixel units adjacent to each other in the first direction is cut by arranging the partition structure, thereby avoiding the leakage current between the two pixel units. In this case, a leakage luminescence phenomenon due to a small space between the two pixel units may be avoided and an image display effect is ensured. The display panel may be fabricated with the existing semiconductor fabrication process, hence the fabrication process is relatively simple and the fabrication cost is low.

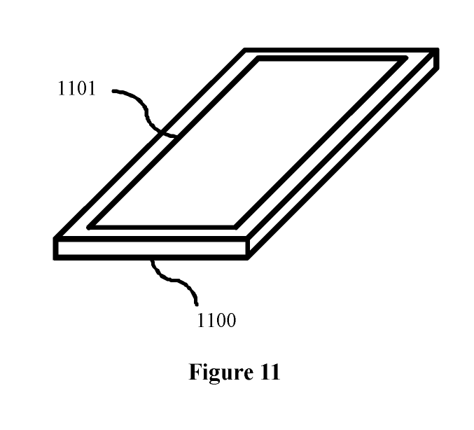

Based on the above embodiments of display panel, an electronic device 1100 including a display panel 1101 being any one of the display panels described in the above embodiment is provided according to an embodiment of the present disclosure. The electronic device 1100 is shown in FIG. 11, which is a schematic structural diagram of the electronic device 1100 including the display panel 1101 according to an embodiment of the present disclosure.

The electronic device 1100 may be an electronic device having a display function, such as a cell phone, a laptop, a tablet computer and a television. Since the display panel 1101 according to the above embodiments is adopted in the electronic device 1100, an image display effect is good and a fabrication cost is low.

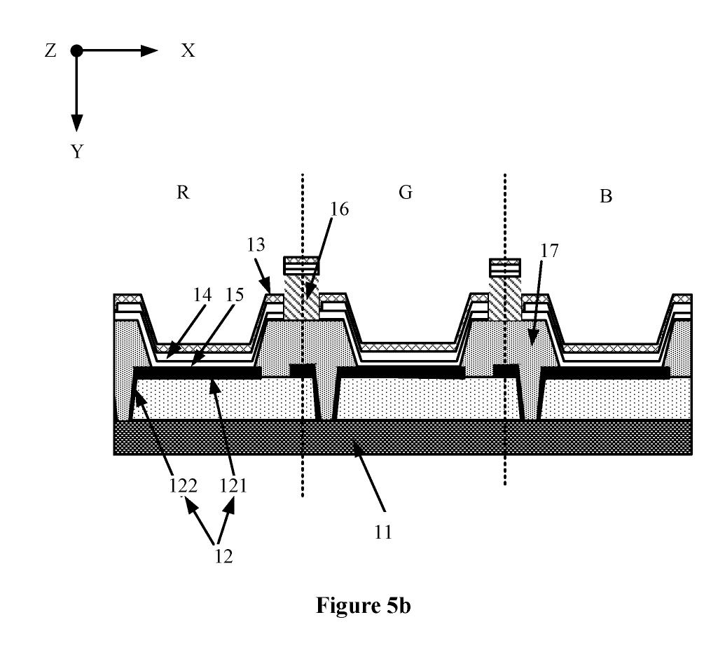

Based on the above embodiments of display panel, a fabrication method for fabricating the display panel according to the above embodiments is provided according to an embodiment of the present disclosure. The fabrication method is shown in FIG. 6.

Reference is made to FIG. 6, which is a schematic flowchart of the fabrication method according to the embodiment of the present disclosure. The fabrication method includes step S11 to step S15.

In step S11, a substrate is prepared.

The substrate is a TFT array substrate including multiple thin-film transistors, and the thin-film transistor is used for a display driving and/or a touch driving.

In step S12, an anode layer is formed on a surface of the substrate.

As described above, the substrate is the TFT array substrate. In this case, in forming the anode layer, an insulation layer needs to be formed on the surface of the substrate, the insulation layer is etched by a photoetching process to form a via hole, and then the anode layer is formed on a surface of the insulation layer having the via hole. The anode layer may be formed by an evaporation process, and the anode layer is electrically connected to thin-film transistors corresponding to the anode layer through the via hole.

In step S13, the anode layer is patterned to form multiple anodes arranged in an array.

The anode layer may be patterned by a photoetching process to form multiple anodes. And the anodes correspond to pixel units respectively.

In step S14, a luminescent function layer is formed on a surface of the patterned anode layer.

The luminescent function layer includes at least one sub-function layer and includes multiple pixel units arranged in an array. The pixel units are arranged respectively opposite to the anodes in a direction perpendicular to the substrate. A partition structure is arranged between two of the pixel units adjacent to each other in a first direction, the partition structure is configured to break at least one sub-function layer at a location between the two of the pixel units. The first direction is parallel to the substrate.

With the partition structure, at least one sub-function layer is broken at a location between the two of the pixel units adjacent to each other in the first direction and a leakage current between the two of the pixel units is avoided, thereby avoiding a leakage luminescence phenomenon and ensuring an image display effect of a final fabricated display panel.

In step S15, a cathode layer is formed on a surface of the luminescent function layer.

The cathode layer may include multiple cathode units respectively corresponding to the anodes. Alternatively, the cathode layer may be an entire conductive layer.

In the fabrication method, after the anode layer is patterned and before the luminescent function layer is formed on the surface of the patterned anode layer, a pixel definition structure is further formed. A method for forming the pixel definition structure includes step S21 to step S22.

In step S21, a pixel definition layer is formed on a side of the anode layer.

In step S22, the pixel definition layer is patterned to expose at least a portion of the anode layer corresponding to the pixel units, with the exposed portion of the anode layer being the luminescent region of the anode layer.

The pixel definition layer may be patterned by a photoetching process. The pixel definition structure is formed after the pixel definition layer is patterned. The pixel definition structures lead to multiple pixel regions respectively corresponding to the pixel units of the display panel.

The etched portions of the pixel definition layer form pixel opening regions respectively corresponding to the pixel units, and un-etched portions of the pixel definition layer form the pixel definition structures. The partition structure is formed above the pixel definition structure.

In some embodiments, in the fabrication method, forming the sub-function layer having the partition structure may include: forming the sub-function layer with a mask having a preset shape by an evaporation process. The mask includes a strip occlusion region extending in the second direction Z, and the strip occlusion region is configured to form an opening in the sub-function layer in the evaporation process for forming the sub-function layer.

Generally, the luminescent function layer includes multiple sub-function layers. The sub-function layer, in which the opening is formed as the partition structure, may be formed with the mask by the evaporation process.

In some embodiments, forming the cathode layer on the surface of the luminescent function layer may include: forming the cathode layer on the surface of the luminescent function layer with the mask by an evaporation process. The strip occlusion region is configured to form an opening in the cathode layer in the evaporation process for forming the cathode layer. In the direction perpendicular to the substrate, the opening in the cathode layer is arranged opposite to the opening in the sub-function layer. In the embodiment, both the cathode layer and preset sub-function layers of the luminescent function layer are formed with a same mask by evaporation processes to form openings, thereby reducing the use of mask and reducing the fabrication cost. With the embodiment, the display panel shown in FIG. 1 may be fabricated.

In some embodiments, forming the cathode layer on the surface of the luminescent function layer may include: forming the cathode layer on the surface of the luminescent function layer by an evaporation process. In the embodiment, an opening is only formed in a preset sub-function layer of the luminescent function layer, and the cathode layer is an entire conductive layer formed by the evaporation process. With the embodiment, the display panel shown in FIG. 2 may be fabricated.

In the above fabrication method, the partition structure is the opening formed in the luminescent function layer. The opening is formed, as the partition structure, in the luminescent function layer with a mask having a preset structure by an evaporation process. It should be noted and understood by those skilled in the art that, the manner of forming the opening in the luminescent function layer by forming the luminescent function layer with the mask having the preset structure by the evaporation process is only a preferred embodiment of the present disclosure. According to the present disclosure, the opening may be formed in the luminescent function layer by depositing an entire luminescent function layer, and then the deposited luminescent function layer is patterned by photoetching or laser. Moreover, in a case that technical condition and process condition permit, in the above fabrication method for forming the opening in the cathode layer, an entire cathode layer may be deposited, and then the deposited cathode layer may be patterned by photoetching or laser, which implementation is adopted depending on the circumstances, and is not limited herein.

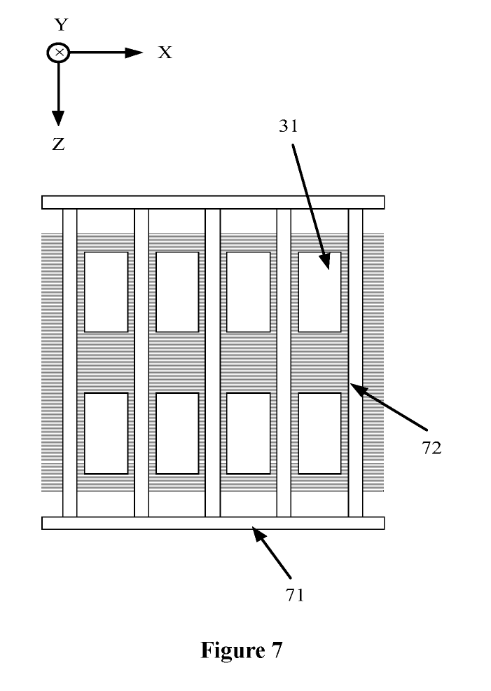

In other embodiments, the partition structure may be a protrusion structure formed between two pixel units. In this case, in the above fabrication method, the method for forming the luminescent function layer on the surface of the patterned anode layer and forming the cathode layer on the surface of the luminescent function layer is shown in FIG. 8.

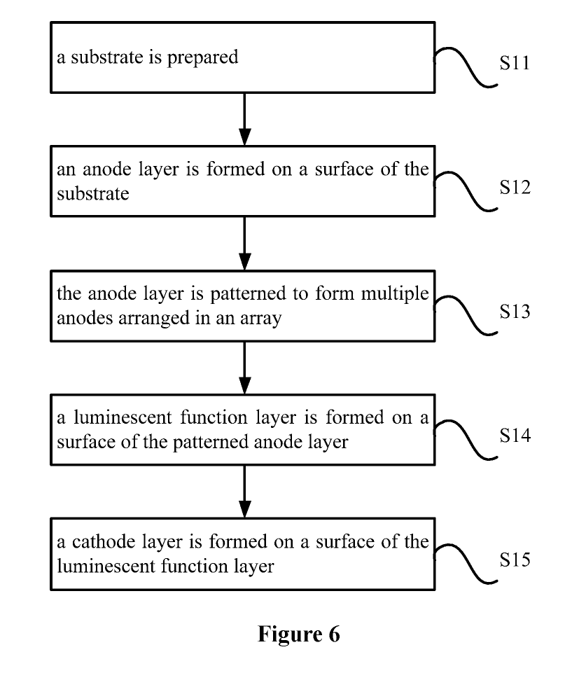

In a case that the partition structure is the opening arranged in the luminescent function layer, as described above, the luminescent function layer may be formed with the mask having the preset shape, and the structure of a strip mask is shown in FIG. 7. FIG. 7 is a schematic diagram of a principle of forming a luminescent function layer according to an embodiment of the present disclosure. The opening is formed, as the partition structure, in the luminescent function layer at the location between two pixel units 31 adjacent to each other in the first direction X, the luminescent function layer may be formed by an evaporation process. And in the evaporation process for forming the luminescent function layer, a mask 71 may be adopted. The mask 71 has a strip occlusion region 72 extending in the second direction Z, and in the evaporation process for forming the sub-function layer, the strip occlusion region is configured to form an opening extending in the second direction in the sub-function layer. In this case, a structure of the formed display panel is as shown in FIG. 3.

Reference is made to FIG. 8, which is a schematic flowchart of a method for forming a luminescent function layer and a cathode layer according to an embodiment of the present disclosure. The method includes step S31 to step S32.

In step S31, a pixel definition structure is formed on the surface of the anode layer and a protrusion structure is formed on a surface of the pixel definition structure.

In step S32, the luminescent function layer and the cathode layer are formed on a side of the substrate on which the anode layer is arranged by an evaporation process, and the luminescent function layer is arranged between the cathode layer and the anode layer.

The protrusion structure is configured to break the luminescent function layer and the cathode layer at a location corresponding to the protrusion structure. In a case that a height of the protrusion structure is greater than a preset height and an angle between a lateral surface of the protrusion structure and a bottom surface of the protrusion structure is larger than a preset angle, the luminescent function layer and the cathode layer may be broken at the protrusion location by the protrusion structure when the luminescent function layer and the cathode layer are formed by an evaporation process. The display panel fabricated according to the embodiment is as shown in FIG. 5. All sub-function layers of the luminescent function layer may be broken by the protrusion structure, thereby avoiding a leakage current between two pixel units respectively on two sides of the protrusion structure and avoiding a leakage luminescence phenomenon.

In some embodiments, the preset height may be 2 micrometers, and the preset angle may be 85 degrees. It should be noted that, in a case that the preset angle is larger than 90 degrees, the protrusion structure is shown as an inverted trapezoidal structure in FIG. 5, that is, a length of an upper surface of the protrusion structure is greater than a length of a lower surface of the protrusion structure.

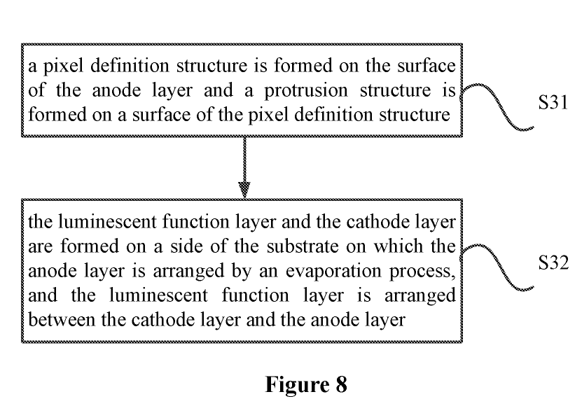

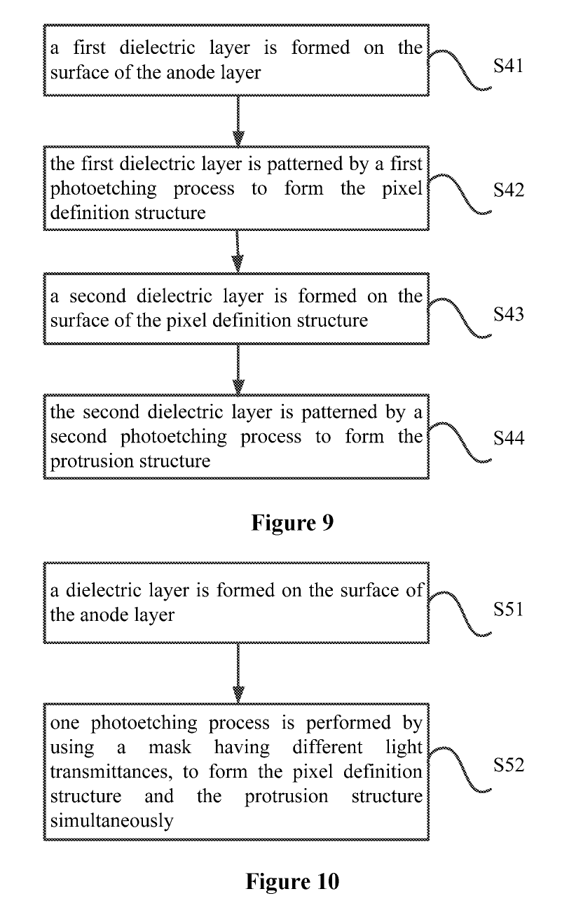

In the embodiment shown in FIG. 8, the protrusion structure may be formed with methods shown in FIG. 9 and FIG. 10.

Reference is made to FIG. 9, which is a schematic flowchart of a method for fabricating a protrusion structure according to an embodiment of the present disclosure. The method includes step S41 to step S44.

In step S41, a first dielectric layer is formed on the surface of the anode layer.

In step S42, the first dielectric layer is patterned by a first photoetching process to form the pixel definition structure.

In step S43, a second dielectric layer is formed on the surface of the pixel definition structure.

In step S44, the second dielectric layer is patterned by a second photoetching process to form the protrusion structure.

In this embodiment, the pixel definition structure is formed by the first photoetching process and the protrusion structure is formed by the second photoetching process. Materials of the first and second dielectric layers may be the same or different. And the display panel fabricated according to the embodiment is as shown in FIG. 5a or FIG. 5b.

Reference is made to FIG. 10, which is a schematic flowchart of a method for fabricating a protrusion structure according to another embodiment of the present disclosure. The method includes step S51 to step S52.

In step S51, a dielectric layer is formed on the surface of the anode layer.

In step S52, one photoetching process is performed by using a mask having different light transmittances, to form the pixel definition structure and the protrusion structure simultaneously.

In the embodiment, one dielectric layer is adopted, and the pixel definition structure and the protrusion structure may be formed simultaneously by performing one photoetching process with the mask having different light transmittances. And the display panel fabricated according to the embodiment is as shown in FIG. 5a.

As can be seen from the above description, in the fabrication method according to the embodiments of the present disclosure, the display panels according to the above embodiments may be fabricated by the existing semiconductor fabrication process, hence the fabrication process is simple and the fabrication cost is low.

According to the above description of the disclosed embodiments, those skilled in the art can implement or practice the present disclosure. Many changes to these embodiments are apparent for those skilled in the art, and general principles defined herein may be implemented in other embodiments without departing from the spirit or scope of the present disclosure. Hence, the present disclosure is not limited to the embodiments disclosed herein, but is to conform to the widest scope in accordance with the principles and novel features disclosed herein.

1. A display panel comprising:
a substrate;
an anode layer and a cathode layer, wherein the anode layer and the cathode layer are arranged on a same side of the substrate and opposite to each other in a direction perpendicular to the substrate, the anode layer being arranged between the substrate and the cathode layer and comprising a plurality of anodes;
a luminescent function layer, wherein the luminescent function layer is arranged between the anode layer and the cathode layer, the luminescent function layer comprising at least one sub-function layer and a plurality of pixel units arranged in an array, wherein the pixel units are arranged respectively opposite to the anodes in the direction perpendicular to the substrate, and
a partition structure arranged between at least two of the pixel units adjacent to each other in a first direction, the partition structure being configured to break at least one sub-function layer at a location between the at least two of the pixel units, wherein the first direction is parallel to the substrate.

2. The display panel according to claim 1, wherein a pixel definition structure is arranged between two of the pixel units adjacent to each other in the first direction, and wherein
the anode layer further comprises a luminescent region, and
in the direction perpendicular to the substrate, a projection of the pixel definition structure on a surface of the substrate does not overlap with a projection of the luminescent region on the surface of the substrate.

3. The display panel according to claim 2, wherein, in the direction perpendicular to the substrate, a projection of the partition structure on the surface of the substrate does not overlap with the projection of the luminescent region on the surface of the substrate.

4. The display panel according to claim 2, wherein the partition structure is further configured to break the cathode layer at the location between the at least two of the pixel units.

5. The display panel according to claim 2, wherein the partition structure extends in a second direction perpendicular to the first direction; and
the display panel comprises a display region, and the partition structure passes through a region between the at least two of the pixel units adjacent to each other in the first direction.

6. The display panel according to claim 5, wherein the partition structure passes through the display region.

7. The display panel according to claim 5, wherein the partition structure is an opening formed in a sub-function layer at the location between the at least two of the pixel units, and the opening is located on a side of the pixel definition structure facing away from the substrate.

8. The display panel according to claim 5, wherein the partition structure is a protrusion structure arranged between the at least two of the pixel units, the protrusion structure is located on a side of the pixel definition structure facing away from the substrate and is configured to break the cathode layer and the luminescent function layer at the location between the at least two of the pixel units.

9. The display panel according to claim 1, wherein the pixel units comprises a first color pixel unit, and wherein in the first direction, the partition structure is arranged between the first color pixel unit and a set of pixel units located on two sides of the first color pixel unit, the set of pixel units being adjacent to the first color pixel unit.

10. The display panel according to claim 1, wherein a distance between two of the pixel units adjacent to each other in the first direction is shorter than a preset distance.

11. An electronic device comprising a display panel, wherein the display panel comprises:
a substrate;
an anode layer and a cathode layer, wherein the anode layer and the cathode layer are arranged on a same side of the substrate and opposite to each other in a direction perpendicular to the substrate, the anode layer being arranged between the substrate and the cathode layer and comprising a plurality of anodes;
a luminescent function layer, wherein the luminescent function layer is arranged between the anode layer and the cathode layer, the luminescent function layer comprising at least one sub-function layer and a plurality of pixel units arranged in an array, wherein the pixel units are arranged respectively opposite to the anodes in the direction perpendicular to the substrate, and
a partition structure arranged between at least two of the pixel units adjacent to each other in a first direction, the partition structure being configured to break at least one sub-function layer at a location between the at least two of the pixel units, wherein the first direction is parallel to the substrate.

12. A fabrication method for fabricating a display panel, wherein the display panel comprises:
a substrate;
an anode layer and a cathode layer, wherein the anode layer and the cathode layer are arranged on a same side of the substrate and opposite to each other in a direction perpendicular to the substrate, the anode layer being arranged between the substrate and the cathode layer and comprising a plurality of anodes; and
a luminescent function layer arranged between the anode layer and the cathode layer, and wherein the fabrication method comprises:
preparing the substrate;
forming the anode layer on a surface of the substrate;
patterning the anode layer to form the plurality of anodes arranged in an array;
forming the luminescent function layer on a surface of the patterned anode layer; and
forming the cathode layer on a surface of the luminescent function layer; and, wherein
the luminescent function layer comprises at least one sub-function layer and a plurality of pixel units arranged in an array, the pixel units being arranged respectively opposite to the anodes in a direction perpendicular to the substrate, wherein
a partition structure is arranged between two of the pixel units adjacent to each other in a first direction, the partition structure being configured to break at least one sub-function layer at a location between the two of the pixel units, wherein the first direction is parallel to the substrate.

13. The fabrication method according to claim 12, further comprising:
before forming the luminescent function layer on the surface of the patterned anode layer:
forming a pixel definition layer on a side of the anode layer; and
patterning the pixel definition layer to expose at least a portion of the anode layer corresponding to the pixel units.

14. The fabrication method according to claim 13, wherein forming the sub-function layer having the partition structure comprises:
forming the sub-function layer with a mask having a preset shape by an evaporation process, wherein
the mask comprises a strip occlusion region extending in a second direction, and the strip occlusion region is configured to form an opening in the sub-function layer in the evaporation process for forming the sub-function layer.

15. The fabrication method according to claim 14, wherein forming the cathode layer on the surface of the luminescent function layer comprises:
forming the cathode layer on the surface of the luminescent function layer with the mask by an evaporation process; and, wherein
the strip occlusion region is configured to form an opening in the cathode layer in the evaporation process for forming the cathode layer, the opening in the cathode layer being arranged opposite to the opening in the sub-function layer in the direction perpendicular to the substrate.

16. The fabrication method according to claim 14, wherein forming the cathode layer on the surface of the luminescent function layer comprises:
forming the cathode layer on the surface of the luminescent function layer by an evaporation process.

17. The fabrication method according to claim 12, wherein forming the luminescent function layer on the surface of the patterned anode layer and forming the cathode layer on the surface of the luminescent function layer comprise:
forming a pixel definition structure on the surface of the anode layer and forming a protrusion structure on a surface of the pixel definition structure; and
forming, by an evaporation process, the luminescent function layer and the cathode layer on a side of the substrate on which the anode layer is arranged, with the luminescent function layer being arranged between the cathode layer and the anode layer; and, wherein
the protrusion structure is configured to break the luminescent function layer and the cathode layer at a location corresponding to the protrusion structure.

18. The fabrication method according to claim 17, wherein forming the pixel definition structure on the surface of the anode layer and forming the protrusion structure on the surface of the pixel definition structure comprises:
forming a first dielectric layer on the surface of the anode layer;
patterning the first dielectric layer by a first photoetching process to form the pixel definition structure;
forming a second dielectric layer on the surface of the pixel definition structure; and
patterning the second dielectric layer by a second photoetching process to form the protrusion structure.

19. The fabrication method according to claim 17, wherein forming the pixel definition structure on the surface of the anode layer and forming the protrusion structure on the surface of the pixel definition structure comprises:
forming a dielectric layer on the surface of the anode layer; and
performing one photoetching process by using a mask having different light transmittances to form the pixel definition structure and the protrusion structure simultaneously.
